(19) United States
(12) Patent Application Publication
(10) Pub. No.: US 2007/0293034 A1
(43) Pub. Date: Dec. 20, 2007

(54) Unlanded via process without plasma damage

(75) Inventors: Tuung Luoh, Taipei City (TW); Ling-Wuu Yang, Hsinchu City (TW); Kuang-Chao Chen, Hsinchu County (TW)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Macronix International Co., Ltd.

(21) Appl. No.: 11/453,000

(22) Filed: Jun. 15, 2006

(51) Int. Cl. H01L 21/4763

(52) U.S. Cl. 438/618

(57) ABSTRACT

A semiconductor device with an unlanded via having an air gap dielectric layer and a silicon-rich oxide (SRO) inter-metal dielectric (IMD) layer, and a method of making the same are provided. The SRO layer acts as an etch-stop layer to prevent unlanded via penetration completely through the IMD layer. In addition, the SRO has a higher extinction coefficient (k) than conventional high-density plasma (HDP) oxide layers, thereby preventing plasma etch damage and excessive void formation in an unlanded via.

### TECHNICAL FIELD

The present invention relates to a semiconductor device and manufacturing method. More particularly, this invention relates to a semiconductor device including a metal wiring layer, a first oxide layer including oxygen and silicon on the wiring layer, a dielectric (IMD) layer to improve reliability, without plasma damage to the semiconductor and a second oxide layer on the first oxide layer, and a manufacturing method therefor.

### BACKGROUND INFORMATION

High-density integrated circuits (IC) are made up of devices, such as field-effect transistors (FETs) and bipolar devices formed in and on a semiconductor substrate, and include multi-level interconnect structures that are used to form connections to and between the various devices. In addition, many high density integrated circuits include closely spaced arrays of devices that are accessed by and connected to one or more arrays of parallel wiring lines formed above the substrate and the devices.

To achieve connections between multiple wiring levels, a vertical interconnect (e.g., a “via” or “plug”) is formed between the top of a first level wiring line and bottom of a second level wiring line, separated by an inter-metal dielectric layer. Aspects of conventional unlanded via formation are illustrated in FIGS. 1-3.

FIG. 1 shows a semiconductor substrate 100 on which a patterned first level metal wiring layer 110 is formed. For simplicity, active device regions between semiconductor substrate 100 and patterned first level metal wiring layer 110 are not depicted. Often, a barrier layer, such as Ti/TiN barrier layer 120, is formed over the patterned first level metal wiring layer 110. After the first level wiring line is formed, an inter-metal dielectric (IMD) layer 130 is provided, such as a high-density plasma (HDP) oxide layer. These inter-metal dielectric layers may include an undesirable air-gap region 140 formed during HDP oxide deposition between metal patterns within a given level of wiring lines. A plasma-enhanced chemical vapor deposition (PECVD) process is then used to deposit an oxide layer 150 over the IMD layer 130. After chemical mechanical polishing (CMP) of the PECVD oxide layer 150 (to reduce topographical variations 160), a capped oxide layer 200 is formed, as shown in FIG. 2.

As shown in FIG. 3, a via etch opening 300 is then formed through the IMD layer 130, to form a via, exposing a portion of the end of the first level wiring line. Metal (not shown) is provided to fill the via and then a wiring line (not shown) is formed over the metal plug within the via to complete the connection. In conventional via formation processes, it is difficult to avoid damage to the underlying active device region and/or substrate region by overetching the via trench. The presence of an air-gap region 140 formed during HDP oxide deposition exacerbates the problem in conventional via formation processes.

This is because the via etch process typically is designed to include a sufficient level of overetching to ensure that the surface of the first level wiring line is exposed in the via etch process. It is generally impractical to rely on optical or other endpoint detection techniques for determining the endpoint of the via etch process. Consequently, it may be difficult to detect etching endpoints with satisfactory reliability. By necessity then, via etching is often a fixed time operation which incorporates a predefined level of overetching by design, possibly causing damage to the underlying active device region and/or substrate region. The presence of an air-gap 140 provides an undesirable shortcut path for etching to proceed below the level of wiring layer 110 and into substrate 100. Moreover, via etching is often performed in a UV plasma, which can degrade underlying oxide films, such as a gate oxide film. Exemplary via etch damage to the substrate is shown by region 310 in FIG. 3.

In addition to overetching damage concerns, when wiring lines are made to have a width near or at the resolution limit of particular lithography equipment used during processing, unlanded vias will likely be formed. Unlanded vias are vertical interconnect structures that extend beyond the edge of a metal wiring line or other conductor to which the desired connection is to be made. Unlanded vias are often unavoidable in conventional semiconductor IC processes, because the vias are formed having a width about equal to the wiring lines they contact. Any misalignment of the via results in a portion of the via being positioned over the edge of the wiring line and, hence, the via is unlanded. Via etch opening 300 in FIG. 3 illustrates this aspect of an unlanded via.

In the case of an unlanded via, as shown in FIG. 3, portions of the via are disposed partially off of the metal wiring line and extend down beneath the surface level of the metal wiring line. The sides of the metal wiring line beneath this surface level are then exposed during etching. These exposed regions typically have a high aspect ratio, and can extend into the substrate, as shown by region 310 in FIG. 3. In addition, the exposed regions lack an etch-stop material, and devices adjacent to the metal wiring line may fail if the metal wiring lines and the substrate are overetched during via formation.

Accordingly, unlanded vias can introduce poor connections between metal layers. In addition, unlanded vias can trap impurities, and can create parasitic electrical resistance between metal layers. Moreover, poor via contacts can be a significant mode of failure among submicron devices.

Therefore, there is a need to prevent both etching through the inter-metal dielectric layer and plasma etch damage to the underlying device to improve reliability in devices with unlanded vias.

The present invention is directed to overcome one or more of the problems of the prior art.

### SUMMARY OF THE INVENTION

Additional features and advantages of the invention will be set forth in the description that follows, being apparent from the description or learned by practice of the invention. The features and advantages of the invention will be realized and attained by the semiconductor device structures and methods of manufacture particularly pointed out in the written description and claims, as well as the appended drawings.

To achieve these and other advantages, and in accordance with the purpose of the invention as embodied and broadly described, there is provided a semiconductor device, including a substrate, a patterned metal wiring layer provided on the substrate, a first oxide layer on and around the patterned metal wiring layer, wherein the first oxide layer includes oxygen and silicon, with a ratio of atoms of silicon to atoms of oxygen exceeding 1:1, and a second oxide layer formed on the first oxide layer.

In accordance with the present invention, there is also provided a semiconductor device, including a substrate, a patterned metal wiring layer provided on the substrate, a first oxide layer on and around the patterned metal wiring layer, wherein the first oxide layer includes oxygen and silicon, with a ratio of atoms of silicon to atoms of oxygen exceeding 1:1, a second oxide layer formed on the first oxide layer, the first oxide layer and second oxide layer collectively having a thickness, and an unlanded via that extends a depth into the first oxide layer and the second oxide layer, the depth being less than the thickness.

In accordance with the present invention, there is also provided a process for manufacturing a semiconductor device, including providing a substrate, forming a patterned metal wiring layer on the substrate, forming a first oxide layer on and around the patterned metal wiring layer, wherein forming the first oxide layer includes combining oxygen and silicon, with a ratio of atoms of silicon to atoms of oxygen exceeding 1:1, performing chemical mechanical polishing on the first oxide layer, and forming a second oxide layer.

In accordance with the present invention, there is further provided a process for manufacturing a semiconductor device, including providing a substrate, forming a patterned metal wiring layer on the substrate, forming a first oxide layer on and around the patterned metal wiring layer, wherein forming the first oxide layer includes combining oxygen and silicon, with a ratio of atoms of silicon to atoms of oxygen exceeding 1:1, performing chemical mechanical polishing on the first oxide layer, forming a second oxide layer, and forming an unlanded via that extends a depth into the first oxide layer and the second oxide layer, the depth being less than the thickness.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are incorporated in and constitute a part of this specification, illustrate embodiments of the invention and, together with the description, serve to explain the features, advantages, and principles of the invention.

In the drawings:

FIGS. 1-3 illustrate aspects of conventional unlanded via formation; and

FIGS. 4-6 illustrate the steps of improved unlanded via formation consistent with the present invention.

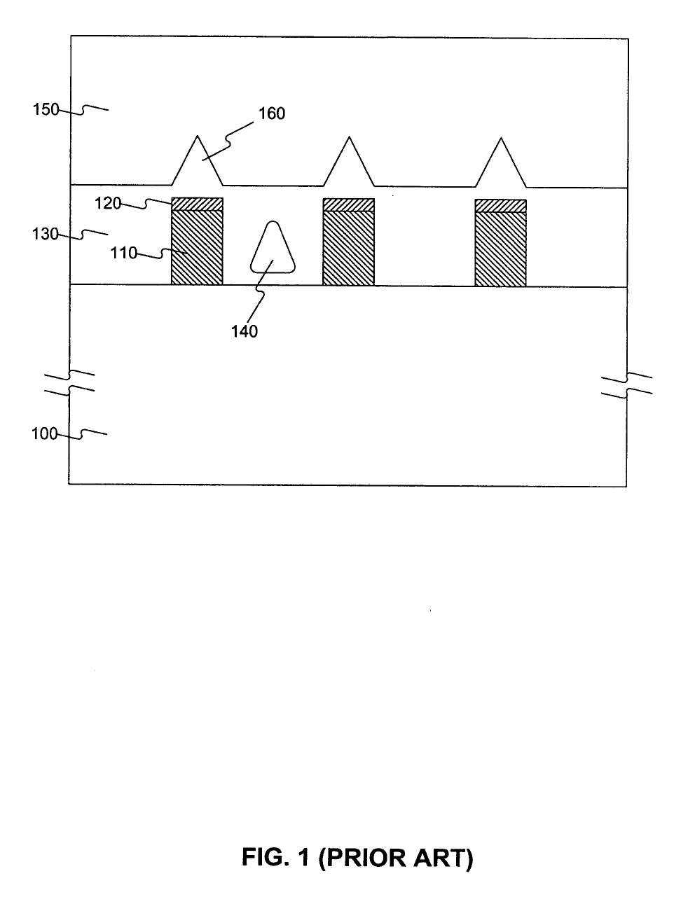

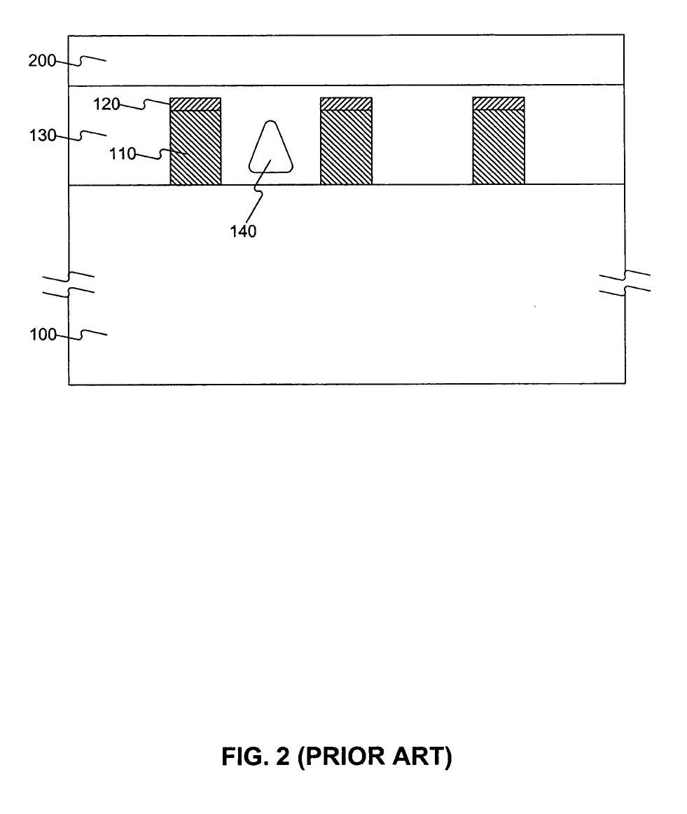

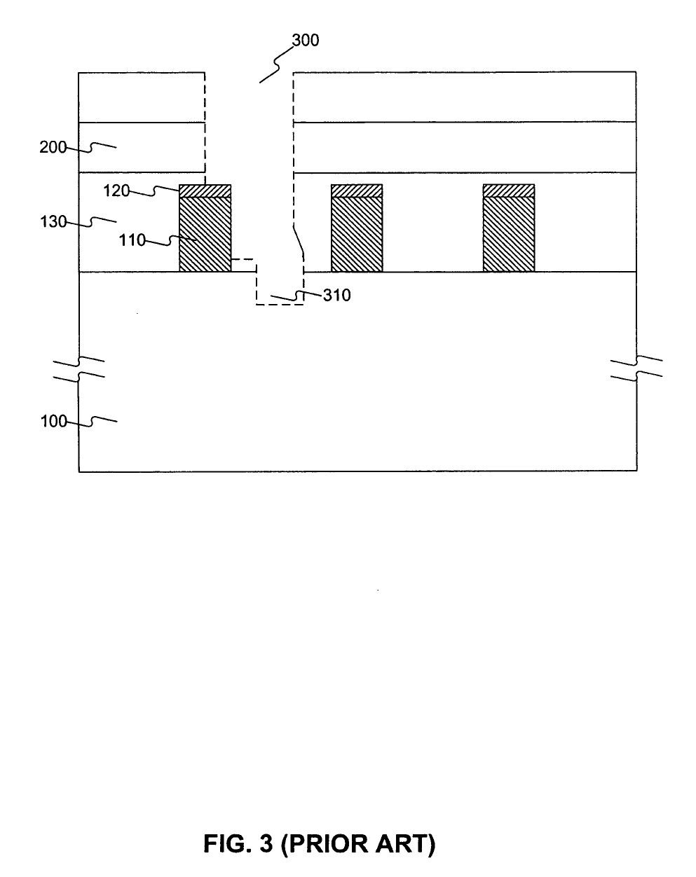

### DESCRIPTION OF THE EMBODIMENTS

Reference will now be made in detail to embodiments of the present invention, examples of which are illustrated in the accompanying drawings. Wherever possible, the same reference numbers will be used throughout the drawings to refer to the same or like parts.

Embodiments consistent with the present invention provide for a silicon-rich oxide (SRO) inter-metal dielectric (IMD) in an unlanded via in a semiconductor device and a manufacturing method thereof. The SRO layer acts as an etch-stop layer to prevent unlanded via penetration through the IMD layer, and consequently overcomes problems associated with conventional unlanded vias described previously, and improves device reliability and manufacturing yield. Furthermore, the SRO used in the present invention has a higher extinction coefficient (k) than conventional HDP oxide layers, thereby effectively preventing plasma etch damage and excessive void formation. The present invention is applicable to FLASH, DRAM, and OTP PROM technology, for example.

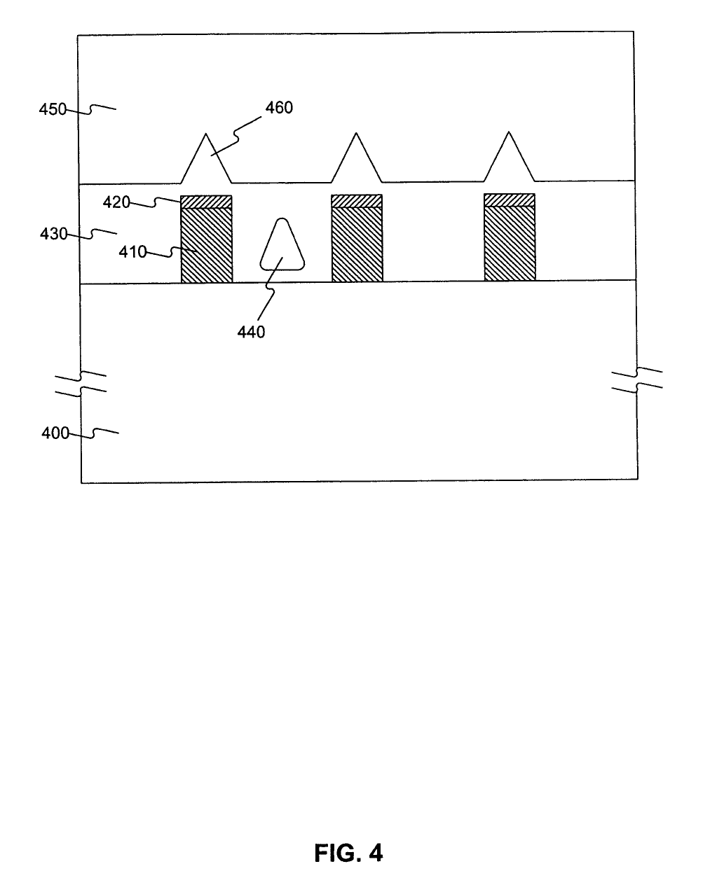

To solve the problems associated with the conventional approaches discussed above and consistent with an aspect of the present invention, a manufacturing method of a semiconductor device consistent with the present invention will next be described with reference to FIGS. 4-6.

FIG. 4 shows a semiconductor substrate 400 on which a patterned first level metal wiring layer 410 is formed. For simplicity, active device regions between substrate 400 and patterned first level metal wiring layer 410 are not depicted. Often, a barrier layer, such as Ti/TiN barrier layer 420 is formed over wiring layer 410. After the first level wiring line is formed, an inter-metal dielectric (IMD) layer 430 is provided. The IMD layer 430 is preferably a high-density plasma (HDP) silicon-rich oxide (SRO).

IMD layer 430 is thus used to electrically insulate wiring layer 410 from adjacent wiring layers, and to serve as a low dielectric constant material (e.g., a “low-k dielectric”) for electrically isolating metal circuits. IMD layer 430 may include an occasional air-gap region 440 formed during deposition of HDP SRO between metal patterns within wiring layer 410.

Consistent with an aspect of the present invention, IMD layer 430 is silicon-rich, and may be formed to comprise a SRO, wherein a ratio of the number of silicon atoms to the number of oxygen atoms in the SRO is much higher than that in SiO₂. As a result, IMD layer 430 contains a large number of dangling silicon bonds. The SRO has a higher optical extinction coefficient as compared to SiO₂. For example, IMD layer 430 formed with SRO may have an optical extinction coefficient of at least 0.5 for wavelengths less than 400 nm. Further, IMD layer 430 formed with SRO may have an extinction coefficient of about 1.3 to about 2.2.

IMD layer 430 may have a thickness of about 300˜1000 nm and may be formed using chemical vapor deposition (CVD) techniques such as plasma-enhanced CVD (PECVD) or high-density plasma chemical vapor deposition (HDPCVD). A source gas combination of SiH₄ and O₂, SiH₄ and N₂O, TEOS and O₂, or TEOS and O₃ may be used in the CVD process, and the flow rates of the gases may be controlled to obtain a desirable silicon-to-oxygen ratio.

As an example, IMD layer 430 may be formed to a thickness of 700 nm by CVD using source gases including SiH₄, O₂, and Ar, in which flow rates of SiH₄, O₂, and Ar are respectively about 50 sccm (standard cubic centimeters per minute), about 100 sccm, and about 50 sccm, with an RF power of about 3000 W. Thus, the ratio of the SiH₄ flow rate to O₂ flow rate is approximately ½. An oxide formed under such conditions has an extinction coefficient of approximately 0 at a wavelength of 248 nm.

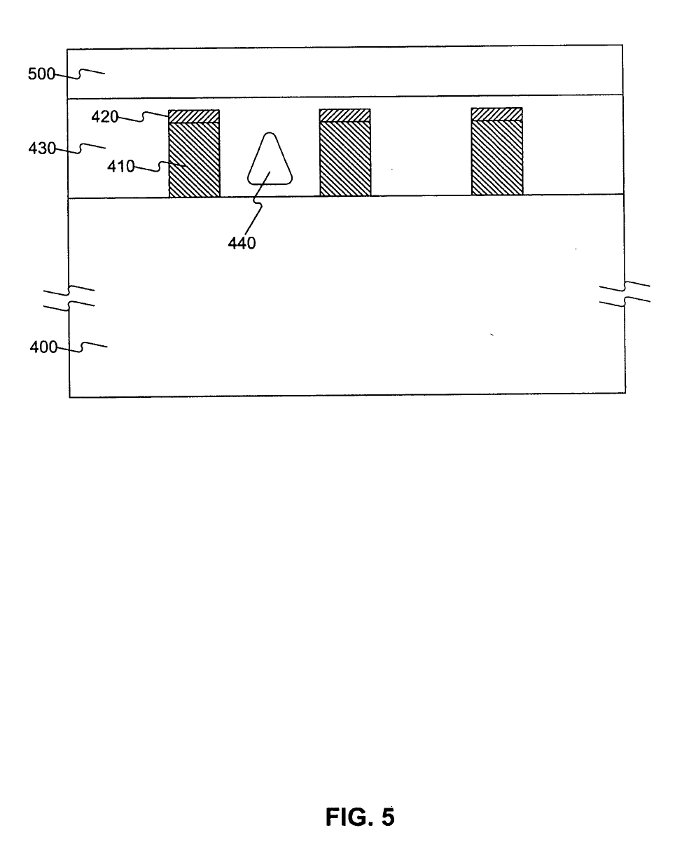

Still referring to FIG. 4, a PECVD process may then be used to deposit an oxide layer 450 over IMD layer 430. Chemical-mechanical polishing (CMP) of oxide layer 450 is performed to reduce topographical variations 460 and planarize IMD layer 430. After CMP of the oxide layer 450, capped oxide layer 500 is formed, as shown in FIG. 5.

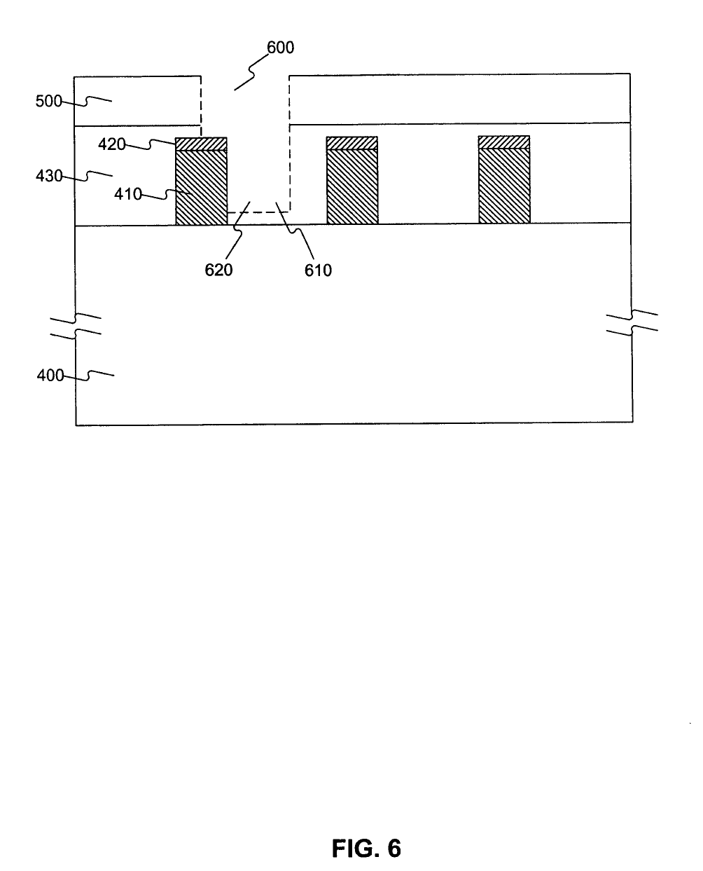

Referring to FIG. 6, a via is then formed by etching a via etch opening 600 that penetrates through the capped oxide layer 500 and a portion of IMD layer 430. Preferably, via etch opening 600 is comparable to the width of the metal layer 410 and barrier 420, for example 2000 nm, to provide a proper landing for a vertical interconnection. Etching serves to expose a portion of the end of the first level wiring line 410 and barrier layer 420 within the via. Preferably, etching may be accomplished by a plasma etching process, such as a dry etching process using a mixture of CH₃F at 70 sccm, CF₄ at 45 sccm, and Ar at 100 sccm. Metal (not shown) is provided to fill the via and then a wiring line is formed over the metal plug within the via to complete the connection. Preferably, the metal is either copper (Cu), aluminum (Al), or Tungsten (W), or a combination thereof, and can be formed by a conventional process, such as CVD or damascene fill.

Still referring to FIG. 6, a region 610 illustrates a portion of the occasional air-gap region 440 that was exposed during the etching of via etch opening 600. A region 620 illustrates another portion of via etch opening 600 to demonstrate that the etch process does not over-etch through the occasional air-gap region 440 and into substrate 400. SRO IMD layer 430 therefore acts as an etch-stop layer because it has a lower etching rate to plasma etching than a conventional HDP oxide layer. This lower etching rate allows for tolerance in both via etching and unlanding, and minimizes damage to the underlying active device regions, metal wiring layers, or substrate. The lower etching rate of SRO IMD layer 430 is due to its greater silicon content.

Therefore, according to the present invention, the SRO IMD layer acts as an etch-stop layer to prevent unlanded via penetration completely through the IMD layer, even in the presence of a region containing voids, and consequently improves device reliability and manufacturing yield. This is in part because the SRO IMD layer has a lower etching rate than conventional IMD layers. Furthermore, the SRO used in the present invention has a higher extinction coefficient (k) than conventional HDP oxide layers, thereby effectively preventing further plasma backend etch damage and excessive void formation.

It will be apparent to those skilled in the art that various modifications and variations can be made in the disclosed structures and methods without departing from the scope or spirit of the invention. Other embodiments of the invention will be apparent to those skilled in the art from consideration of the specification and practice of the invention disclosed herein. It is intended that the specification and examples be considered as exemplary only, with a true scope and spirit of the invention being indicated by the following claims.

What is claimed is:

1. A semiconductor device, comprising:
a substrate;
a patterned metal wiring layer provided on the substrate;
a first oxide layer on and around the patterned metal wiring layer,
wherein the first oxide layer includes oxygen and silicon, with a ratio of atoms of silicon to atoms of oxygen exceeding 1:1; and
a second oxide layer formed on the first oxide layer.

2. A semiconductor device according to claim 1, wherein the patterned metal wiring layer includes at least one of copper, aluminum, and gold, the metal wiring layer further including a barrier metal layer including at least one of titanium and titanium nitride.

3. A semiconductor device according to claim 1, wherein the first oxide layer is a high-density plasma (HDP) layer.

4. A semiconductor device according to claim 1, wherein the first oxide layer is an inter-metal dielectric layer.

5. A semiconductor device according to claim 1, wherein the first oxide layer has an extinction coefficient of about 1.3 to about 2.2.

6. A semiconductor device, comprising:
a substrate;
a patterned metal wiring layer provided on the substrate;
a first oxide layer on and around the patterned metal wiring layer,
wherein the first oxide layer includes oxygen and silicon, with a ratio of atoms of silicon to atoms of oxygen exceeding 1:1;
a second oxide layer formed on the first oxide layer,
the first oxide layer and second oxide layer collectively having a thickness; and
an unlanded via that extends a depth into the first oxide layer and the second oxide layer, the depth being less than the thickness.

7. A semiconductor device according to claim 6, wherein the patterned metal wiring layer includes at least one of copper, aluminum, and gold, the metal wiring layer further including a barrier metal layer including at least one of titanium and titanium nitride.

8. A semiconductor device according to claim 6, wherein the first oxide layer is a high-density plasma (HDP) layer.

9. A semiconductor device according to claim 6, wherein the first oxide layer is an inter-metal dielectric layer.

10. A semiconductor device according to claim 6, wherein first oxide layer has an extinction coefficient of about 1.3 to about 2.2.

11. A semiconductor device according to claim 6, wherein a size of the air-gap dielectric region is determined by filling characteristics of the first oxide layer.

12. A method of manufacturing a semiconductor device, comprising:
providing a substrate;
forming a patterned metal wiring layer on the substrate;
forming a first oxide layer on and around the patterned metal wiring layer,
wherein forming the first oxide layer includes combining oxygen and silicon, with a ratio of atoms of silicon to atoms of oxygen exceeding 1:1;
performing chemical mechanical polishing on the first oxide layer; and
forming a second oxide layer.

13. A method of manufacturing a semiconductor device according to claim 12, wherein forming the patterned metal wiring layer includes depositing at least one of copper, aluminum, and gold, and depositing a barrier metal layer including at least one of titanium and titanium nitride.

14. A method of manufacturing a semiconductor device according to claim 12, wherein forming the first oxide layer includes a high-density plasma (HDP) deposition.

15. A method of manufacturing a semiconductor device according to claim 12, wherein forming the first oxide layer provides an extinction coefficient of about 1.3 to about 2.2.

16. A method of manufacturing a semiconductor device, comprising:
providing a substrate;
forming a patterned metal wiring layer on the substrate;
forming a first oxide layer on and around the patterned metal wiring layer,
wherein forming the first oxide layer includes combining oxygen and silicon, with a ratio of atoms of silicon to atoms of oxygen exceeding 1:1;
performing chemical mechanical polishing on the first oxide layer;
forming a second oxide layer; and
forming an unlanded via that extends a depth into the first oxide layer and the second oxide layer, the depth being less than the thickness.

17. A method of manufacturing a semiconductor device according to claim 16, wherein forming the patterned metal wiring layer includes depositing at least one of copper, aluminum, and gold, and depositing a barrier metal layer including at least one of titanium and titanium nitride.

18. A method of manufacturing a semiconductor device according to claim 16, wherein forming the first oxide layer includes a high-density plasma (HDP) deposition.

19. A method of manufacturing a semiconductor device according to claim 16, wherein forming the first oxide layer provides an extinction coefficient of about 1.3 to about 2.2.
